(19) United States
(12) Patent Application Publication
(10) Pub. No.: US 2026/0287955 A1
(43) Pub. Date: Sep. 24, 2026

(54) ELECTRO-OPTIC DEVICE, METHOD OF MANUFACTURING ELECTRO-OPTIC DEVICE, AND ELECTRONIC APPARATUS

(71) Applicant: SEIKO EPSON CORPORATION, Tokyo (JP)

(72) Inventor: Hidenori KAWATA, CHINO-SHI (JP)

(73) Assignee: SEIKO EPSON CORPORATION, Tokyo (JP)

(21) Appl. No.: 19/572,888

(22) Filed: Mar. 20, 2026

(30) Foreign Application Priority Data
Mar. 21, 2025 (JP) 2025-047374

(51) Int. Cl. G02F 1/1368; H10D 86/01; H10D 86/40

(52) U.S. Cl. CPC G02F 1/1368; H10D 86/0221; H10D 86/421; H10D 86/481

(57) ABSTRACT

An electro-optic device of the present disclosure includes a transistor disposed at a substrate. The transistor includes a semiconductor layer including a channel region, a source region, and a drain region and extending along a first direction, and a gate electrode facing the channel region via an insulating film. An impurity is added to a part of the channel region. In the first direction, an impurity concentration in a central region of the channel region and an impurity concentration in side regions at both sides of the central region are different from each other.

The present application is based on, and claims priority from JP Application Serial Number 2025-047374, filed Mar. 21, 2025, the disclosure of which is hereby incorporated by reference herein in its entirety.

### BACKGROUND

### 1. Technical Field

The present disclosure relates to an electro-optic device, a method of manufacturing an electro-optic device, and an electronic apparatus.

### 2. Related Art

In general, an electro-optic device includes a first substrate, a second substrate, and a liquid crystal layer disposed between the first substrate and the second substrate. A plurality of pixel electrodes that has transmittance with respect to the incident light is disposed at one plate surface of the first substrate. A counter electrode is disposed at a surface of the second substrate opposed to the one plate surface of the first substrate. A pixel of the electro-optic device is formed in a region of each of the pixel electrodes and a portion of the counter electrode opposed to that pixel electrode. A transistor that performs a switching operation of the pixel is formed at an opposite side to a side closer to the liquid crystal layer than to the pixel electrode in the first substrate.

For example, in the electro-optic device disclosed in JP-A-2010-205874, a first transistor in a display region includes a first semiconductor layer formed in an elongated shape including a first channel region having a main body portion and an edge portion, and a first gate electrode facing the first semiconductor layer. A second transistor in the peripheral region includes a second semiconductor layer including a second channel region, and a second gate electrode disposed so as to face the second semiconductor layer. Impurity ions are implanted in the main body portion of the first channel region, whereby impurity ions are implanted in each of the main body portion and the edge portion of the first channel region and further the second channel region at a time of manufacture. A second impurity concentration in the edge portion of the first channel region and a third impurity concentration in the second channel region are higher than a first impurity concentration in the main body portion of the first channel region.

For example, in an electro-optic device disclosed in JP-A-2003-174172, a semiconductor layer made of single crystal silicon of a transistor includes a channel region, a body contact region at a lateral side of the channel region, and a drawing region. The body contact region is formed outside a region overlapping a gate electrode in plan view in the channel region. A p-type impurity diffusion region is formed in a region that is located between the channel region and the body contact region and is located below the gate electrode. The drawing region includes the p-type impurity diffusion region and is formed between the channel region and the body contact region. The impurity concentration in the channel region is higher than the impurity concentration in the impurity diffusion region of the drawing region. The impurity concentration in the impurity diffusion region is higher than the impurity concentration in the body contact region.

JP-A-2010-205874 and JP-A-2003-174172 are examples of the related art.

In an n-type MOS structure of the electro-optic device disclosed in JP-A-2010-205874, the sheet resistance of a low impurity concentration region is high due to an influence of the impurity concentration in the semiconductor layer disposed between the gate electrode and each of the source region and the drain region. Further, in the n-type MOS structure described above, the hump characteristic becomes apparent by adding impurities to the entire semiconductor layer. As a result, in the n-type MOS structure described above, it is difficult to control switching characteristics between an ON state and an OFF state of the transistor. In the transistor of the electro-optic device disclosed in JP-A-2003-174172, in order to activate impurities added to a semiconductor layer, a heat treatment of the semiconductor layer at a high temperature may be performed in some cases, but when the activation is insufficient, a threshold voltage is not stabilized, and it is difficult to control the switching characteristics. Therefore, it is desired to improve the switching characteristics in the related-art electro-optic device.

### SUMMARY

An electro-optic device of an aspect of the present disclosure includes a transistor disposed at a substrate. The transistor includes a semiconductor layer including a channel region, a source region, and a drain region and extending along a first direction, and a gate electrode facing the channel region via an insulating film. An impurity is added to a part of the channel region. In the first direction, an impurity concentration in a central region of the channel region and an impurity concentration in side regions at both sides of the central region are different from each other.

### BRIEF DESCRIPTION OF THE DRAWINGS

FIG. 1 is a plan view of a liquid crystal device of one embodiment of the present disclosure.

FIG. 2 is a cross-sectional view of the liquid crystal device in FIG. 1.

FIG. 3 is an equivalent circuit diagram of the liquid crystal device in FIG. 1.

FIG. 4A is a plan view of a first substrate of the liquid crystal device in FIG. 1.

FIG. 4B is a cross-sectional view of the first substrate in FIG. 4A.

FIG. 4C is a cross-sectional view of the first substrate in FIG. 4A.

FIG. 4D is a cross-sectional view of the first substrate in FIG. 4A.

FIG. 5 is a plan view of a semiconductor layer in a first form constituting a transistor of the liquid crystal device in FIG. 1.

FIG. 6 is a schematic graph showing electrical characteristics of the transistor including the semiconductor layer in FIG. 5.

FIG. 7 is a plan view of a semiconductor layer in a second form constituting a transistor of the liquid crystal device in FIG. 1.

FIG. 8 is a plan view of a semiconductor layer in a third form constituting a transistor of the liquid crystal device in FIG. 1.

FIG. 9 is a schematic diagram of an electronic apparatus according to an embodiment of the present disclosure.

### DESCRIPTION OF EMBODIMENTS

Some embodiments of the present disclosure will hereinafter be described with reference to the drawings. In the drawings, the dimensional scales may be different between the components in some cases in order to make each of the components eye-friendly.

In the following description, an X axis, a Y axis, and a Z axis are used as three axes orthogonal to each other. One side along the X axis is described as a +X side, and a side opposite to the +X side along the X axis is described as a -X side. Similarly, one side along the Y axis is described as a +Y side, and a side opposite to the +Y side along the Y axis is described as a -Y side. One side along the Z axis is described as a +Z side, and a side opposite to the +Z side along the Z axis is described as a -Z side. A plane including the X axis and the Y axis may be described as an "X-Y plane", and a view of the X-Y plane along the Z axis may be described as a "plan view" in some cases.

In the following description, for example, with respect to a substrate, a description "at the substrate" represents one of when something is disposed in contact with an upper surface of the substrate, when something is disposed at the upper surface of the substrate via a component such as a structure other than the substrate, and when a part of something is disposed in contact with the upper surface of the substrate and another part thereof is disposed via a component other than the substrate. The material and dimensions such as the thickness of each of the components of the liquid crystal device of the embodiment are not limited to the illustrated material and dimensions except when the reason that the material and the dimensions are suitable or the like is described.

In one embodiment of the present disclosure, the description will be presented citing, as an embodiment of the electro-optic device, a liquid crystal device of an active drive type including a thin film transistor (TFT) as a switching element for each pixel, and of a transmissive type. In the following description, the thin film transistor may be abbreviated as TFT in some cases. The liquid crystal device is suitably used as a light modulation device in, for example, a projector as an electronic apparatus described later, and corresponds to an electro-optic element.

### Outline of Physical Structure of Liquid Crystal Device

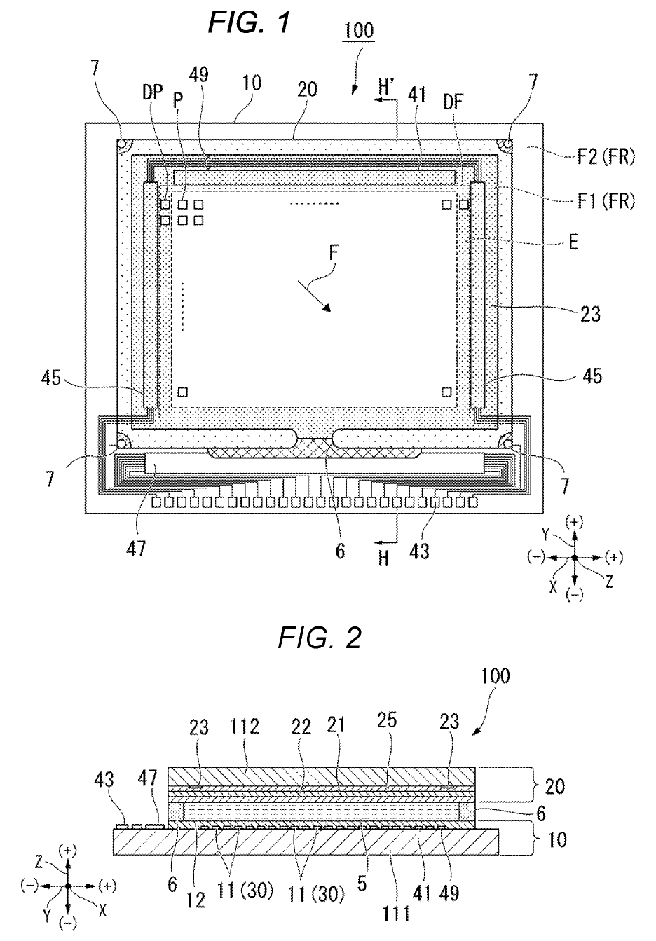

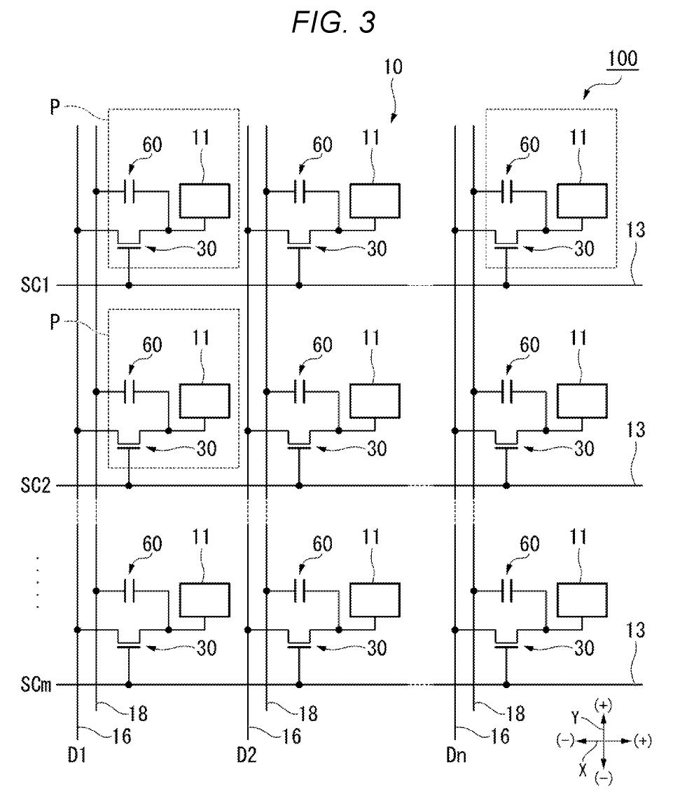

FIG. 1 is a plan view of the liquid crystal device 100 of the present embodiment. FIG. 2 is a cross-sectional view of the liquid crystal device 100, and is a cross-sectional view when viewed along an arrowed line H-H' shown in FIG. 1. As illustrated in FIGS. 1 and 2, the liquid crystal device 100 includes a first substrate 10, a second substrate 20, and a liquid crystal layer 5. The second substrate 20 is disposed so as to face the first substrate 10. The first substrate 10 and the second substrate 20 correspond to a pair of substrates. The liquid crystal layer 5 is sandwiched between the first substrate 10 and the second substrate 20 along the Z axis, and functions as an electro-optic layer in the liquid crystal device 100. The liquid crystal layer 5 includes a plurality of liquid crystal molecules (not illustrated).

As an element substrate 111 of the first substrate 10 and a counter substrate 112 of the second substrate 20, substrates formed of a material capable of transmitting colored light incident on the liquid crystal device 100 are used, and for example, substrates such as glass substrates or quartz substrates are used.

In the plan view, the dimension of the first substrate 10 along the X axis and the dimension thereof along the Y axis are larger than those of the second substrate 20. The first substrate 10 and the second substrate 20 are bonded to each other on the Z axis via a sealing material 6 disposed along an outer edge of the second substrate 20. Liquid crystal having positive or negative dielectric anisotropy is enclosed in a space surrounded by the first substrate 10, the second substrate 20, and the sealing material 6, and thus the liquid crystal layer 5 is provided.

In the plan view, a display region E including a plurality of pixels P is disposed inside the sealing material 6. The plurality of pixels P is arranged in a matrix along the X axis and the Y axis. In the plan view, a region outside the display region E is a peripheral region FR. In the plan view, dummy pixels DP are disposed in a first peripheral region F1 between the sealing material 6 and the display region E out of the peripheral region FR. The first peripheral region F1 surrounds the display region E on the X-Y plane. The dummy pixels DP are arranged in a region of the first peripheral region F1 closest to the display region E. The region where the dummy pixels DP are arranged is a dummy pixel region DF that does not make a contribution to display.

In the plan view, a partition member 23 surrounding the display region E is disposed in the first peripheral region F1. For example, an inspection circuit 41 is disposed in a region between the display region E and the sealing material 6 located on one side extending along the X axis and disposed at the +Y side on the Y axis out of the first peripheral region F1. A scanning line drive circuit 45 is disposed in a region between the display region E and the sealing materials 6 on each of two sides extending along the X axis out of the first peripheral region F1. A plurality of wiring lines 49 coupling the two scanning line drive circuits 45 is disposed in a region between the sealing material 6 and the inspection circuit 41 out of the first peripheral region F1.

A plurality of external coupling terminals 43 is disposed in a second peripheral region F2 of the first substrate 10 located outside the sealing material 6 out of the peripheral region FR. The plurality of external coupling terminals 43 extends along, for example, the X axis. The plurality of external coupling terminals 43 is disposed at intervals along the X axis in the second peripheral region F2 at the -Y side. In the plan view, in the second peripheral region F2, a data line drive circuit 47 is disposed between the region where the plurality of external coupling terminals 43 is disposed and the sealing material 6 extending along the X axis.

The wiring lines 49 are coupled to the data line drive circuit 47 and the scanning line drive circuit 45, and are coupled to the plurality of external coupling terminals 43. Note that the inspection circuit 41 may be disposed in a region different from the region between the display region E and the sealing material 6 on the one side extending along the X axis and disposed at the +Y side.

As illustrated in FIG. 2, thin film transistors 30, the inspection circuit 41, the wiring lines 49, and an alignment film 12 are disposed at a surface facing to the liquid crystal layer 5 in the element substrate 111 as a base member of the first substrate 10. The thin film transistor 30 is a switching element provided for each pixel P. The alignment film 12 covers pixel electrodes 11, the thin film transistors 30, and the wiring lines 49. The thin film transistor 30 and the pixel electrode 11 are components of the pixel P. The first substrate 10 includes the element substrate 111, the pixel electrodes 11, the thin film transistors 30, the wiring lines 49, and the alignment film 12, and is configured with these components and the inspection circuit 41.

The partition member 23, an insulating layer 25, a counter electrode 21, and an alignment film 22 are disposed on a surface facing to the liquid crystal layer 5 in the counter substrate 112 as a base member of the second substrate 20. The insulating layer 25 covers the partition member 23. The counter electrode 21 is disposed as a common electrode disposed to cover the insulating layer 25. The alignment film 22 covers the counter electrode 21. The second substrate 20 includes the partition member 23, the counter electrode 21, and the alignment film 22 and is configured with these components and the insulating layer 25.

Note that the counter electrode 21 as the common electrode is disposed at the second substrate 20 as an example, but may be disposed at the first substrate 10. For example, an insulating layer (not illustrated) that covers the thin film transistors 30, the inspection circuit 41, and the wiring lines 49 may be provided, and the counter electrode 21 may be disposed between the insulating layer (not illustrated) described above and the alignment film 12.

As illustrated in FIG. 1, in the plan view, the scanning line drive circuits 45 and the inspection circuit 41 overlap the partition member 23. The partition member 23 functions as a light-blocking region. Light including colored light or the like and entering the liquid crystal device 100 is emitted from a light source device (not illustrated) and is incident on the second substrate 20 of the liquid crystal device 100 from the +Z side along the Z axis. The partition member 23 blocks the light incident on the liquid crystal device 100 so as not to enter a peripheral circuit such as the scanning line drive circuit 45. Since the partition member 23 is provided, an erroneous operation of the peripheral circuit is prevented. The partition member 23 blocks unnecessary stray light so as not to enter the display region E. Since the partition member 23 is provided, reduction in contrast in the liquid crystal device 100 is prevented.

The insulating layer 25 is formed of an inorganic material such as silicon oxide (SiO₂) having a light transmissive property with respect to the light incident on the liquid crystal device 100. The surface of the insulating layer 25 having contact with the liquid crystal layer 5 is a flat surface parallel to the X-Y plane.

In the plan view, conducting members 7 are disposed in four corners of the sealing material 6 and extend along the Z axis. The counter electrode 21 is electrically coupled to the conducting members 7. The conducting members 7 are electrically coupled to a common wiring line 18 described later.

The pixel electrodes 11 and the counter electrode 21 are formed of a transparent conductive film made of, for example, indium tin oxide (ITO) or indium zinc oxide (IZO). The material of the alignment films 12, 22 is selected based on the optical design of the liquid crystal device 100. Examples of the material of the alignment films 12, 22 include inorganic compounds such as silicon dioxide (SiO₂), titanium dioxide (TiO₂), and magnesium oxide (MgO), and organic compounds such as polyimide.

In the liquid crystal device 100, an optical design in a normally white mode or a normally black mode is adopted, and the optical design in the normally black mode, for example, is adopted. Note that in accordance with the optical design of the liquid crystal device 100, a polarization element (not illustrated) is disposed in each of a space at the incident side of the light and a space at an exit side with respect to the liquid crystal device 100.

The alignment films 12, 22 are appropriately designed based on optical characteristics required for the liquid crystal device 100. In a cross-sectional view along a plane including the Z axis and an F direction, the central axis of each of a plurality of columnar bodies of the alignment films 12, 22 is inclined with respect to at least the Z axis, and moves from a -F side toward a +F side as moving from the -Z side to the +Z side. In an unapplied state in which predetermined voltages are not applied to the plurality of pixel electrodes 11 and the counter electrode 21 of the liquid crystal device 100, the long axes of the plurality of liquid crystal molecules of the liquid crystal layer 5 are aligned with each other by the alignment films 12, 22. That is, the alignment films 12, 22 have a function of aligning the plurality of liquid crystal molecules in the F direction in the unapplied state with the voltages in the liquid crystal device 100.

### Outline of Electrical Structure of Liquid Crystal Device

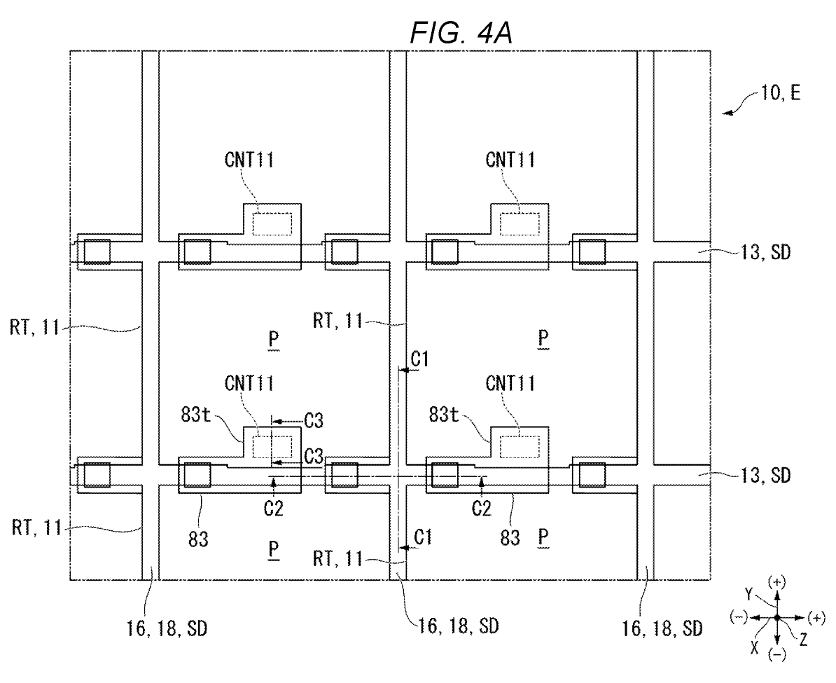

FIG. 3 is an equivalent circuit diagram of the liquid crystal device 100. As illustrated in FIG. 3, in the liquid crystal device 100, a plurality of scanning lines 13, a plurality of data lines 16, and a plurality of common wiring lines 18 are disposed at the element substrate 111 of the first substrate 10. The plurality of scanning lines 13 extends in parallel to the X axis. The plurality of data lines 16 and the plurality of common wiring lines 18 extend in parallel to the Y axis. The plurality of data lines 16 crosses at least the plurality of scanning lines 13. That is, the direction in which the scanning lines 13 extend and the direction in which the data lines 16 extend are different from each other. Note that the plurality of common wiring lines 18 is not necessarily required to extend along the Y axis, and the direction in which the common wiring lines 18 extend is not limited to a specific direction, and the common wiring lines 18 may extend in parallel to the X axis.

The pixels P are sectioned by the scanning lines 13 extending along the X axis and the data lines 16 extending along the Y axis. The pixel P is provided with the pixel electrode 11, the thin film transistor 30, and a capacitive element 60.

The scanning line 13 is electrically coupled to the gate of the thin film transistor 30. The data line 16 is electrically coupled to the source of the thin film transistor 30. The scanning line 13 simultaneously switches the thin film transistors 30 disposed in the same row between an ON state and an OFF state, and simultaneously controls the states of the thin film transistors 30 disposed in the same row. The pixel electrode 11 is electrically coupled to the drain of the thin film transistor 30.

The data lines 16 are electrically coupled to the data line drive circuit 47, and supply the pixels P with the image signals D1, D2, ..., and Dn supplied from the data line drive circuit 47, respectively. The scanning lines 13 are electrically coupled to the scanning line drive circuit 45, and supply the respective pixels P with scanning signals SC1, SC2, ..., and SCm supplied from the scanning line drive circuit 45.

The image signal D1 to the image signal Dn supplied from the data line drive circuit 47 to the data lines 16 may be sequentially supplied, or may be supplied collectively for each group of the plurality of data lines 16 adjacent to each other. The scanning line drive circuit 45 sequentially supplies the scanning signal SC1 to the scanning signal SCm to the scanning lines 13 as pulses at a predetermined timing.

When the scanning signal SC1 is input to the thin film transistor 30, the thin film transistor 30 is set to the ON state for a certain period. Accordingly, the image signal D1 supplied from the data line 16 is written in the pixel electrode 11 at a predetermined timing. The image signal D1 which has a predetermined level and has been written in the liquid crystal layer 5 via the pixel electrode 11 is held for a certain period between the pixel electrode 11 and the counter electrode 21 disposed so as to be opposed to the pixel electrode 11 via the liquid crystal layer 5.

The capacitive element 60 is coupled in parallel and electrically to a liquid crystal capacitor disposed between the pixel electrode 11 and the counter electrode 21. This prevents leakage of the image signal D1 held in the liquid crystal layer 5. The capacitive element 60 is electrically coupled to the pixel electrode 11 and the common wiring line 18.

Although not illustrated in FIG. 3, the inspection circuit 41 is coupled to the data lines 16. Therefore, in a manufacturing process of the liquid crystal device 100, the presence or absence of a failure in an operation of the liquid crystal device 100 can be checked by detecting the image signals D1, D2, ..., and Dn.

### Outline of Electrical Structure of Electro-Optic Element

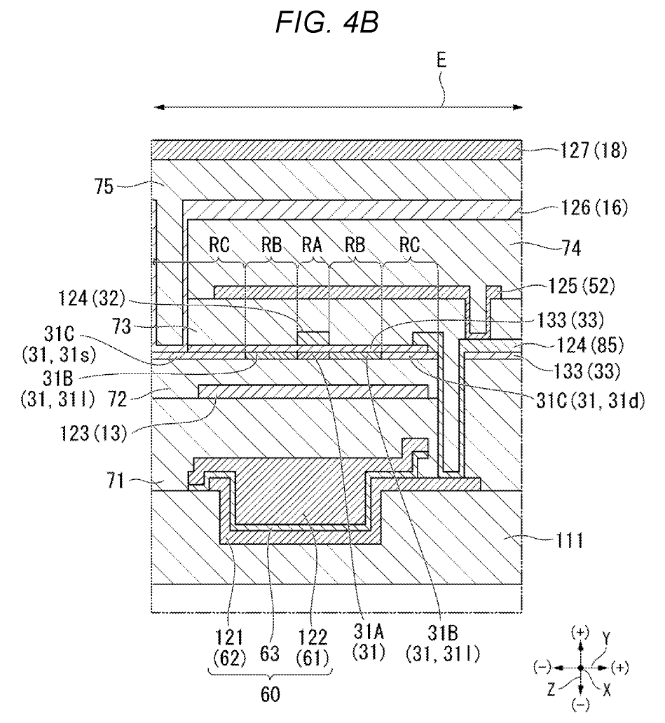

FIG. 4A is a schematic plan view of the pixels P of the liquid crystal device 100 and is a plan view of the first substrate 10. FIG. 4B is a cross-sectional view of the pixel P, and is a diagram when viewed along an arrowed line C1-C1 shown in FIG. 4A. FIG. 4C is another cross-sectional view of the pixel P, and is a diagram when viewed along an arrowed line C2-C2 shown in FIG. 4A. FIG. 4D is a cross-sectional view of the pixel P, and is a diagram when viewed along an arrowed line C3-C3 shown in FIG. 4A. Note that in each of FIGS. 4B to 4D, an upper structure of the pixel P described later is omitted.

As illustrated in FIGS. 4A to 4D, a first conductive layer 121, a second conductive layer 122, a third conductive layer 123, a semiconductor layer 31, a fourth conductive layer 124, a fifth conductive layer 125, a sixth conductive layer 126, and a seventh conductive layer 127 are sequentially stacked at the element substrate 111 from the -Z side toward the +Z side. The pixel electrode 11 is stacked at the +Z side of the seventh conductive layer 127.

The first conductive layer 121 includes a second capacitance electrode 62 of the capacitive element 60. The second conductive layer 122 includes a first capacitance electrode 61 of the capacitive element 60. The third conductive layer 123 is formed of a conductive material having a light-blocking property, and includes the scanning lines 13. The semiconductor layer 31 and the fourth conductive layer 124 configure the thin film transistors 30. As the thin film transistor 30, a top gate structure and a lightly doped drain (LDD) structure are adopted.

The semiconductor layer 31 includes semiconductor layers 31A in first regions RA, semiconductor layers 31B in second regions RB, and semiconductor layers 31C in third regions RC. The fourth conductive layer 124 includes the gate electrodes 32 of the thin film transistors 30. An insulating film 133 as a gate insulating film 33 is disposed between the semiconductor layer 31 and the gate electrode 32 of the fourth conductive layer 124.

The semiconductor layer 31A is disposed so as to be adjacent to the gate electrode 32 in the fourth conductive layer 124 via the gate insulating film 33 along the Z axis. That is, the semiconductor layer 31A is disposed below the gate electrode 32 across the gate insulating film 33. An impurity according to the type of the thin film transistor 30 is implanted into a part of the semiconductor layer 31A. When the thin film transistor 30 has an n-type MOS structure, the impurity added to a part of the semiconductor layer 31A is, for example, boron (B). When the thin film transistor 30 has a p-type MOS structure, the impurity added to a part of the semiconductor layer 31A is, for example, phosphorus (P). A detailed configuration of the semiconductor layer 31A will be described later.

The semiconductor layers 31B are adjacent to the semiconductor layer 31A along the Y axis and are disposed at the +Y side and the -Y side of the semiconductor layer 31A in the semiconductor layer 31. An impurity according to the type of the thin film transistor 30 is implanted into the semiconductor layers 31B. When the thin film transistor 30 has the n-type MOS structure, the impurity added to the semiconductor layers 31B is, for example, phosphorus. When the thin film transistor 30 has the p-type MOS structure, the impurity added to the semiconductor layers 31B is, for example, boron.

The semiconductor layers 31C include the remaining portions in the semiconductor layer 31 other than the semiconductor layers 31A, 31B, are adjacent to the semiconductor layers 31B along the Y axis, and are disposed at the +Y side and the -Y side of the semiconductor layers 31B. An impurity substantially the same as that of the semiconductor layers 31B is implanted into the semiconductor layers 31C. Note that the impurity concentration in the semiconductor layers 31C in the third regions RC is higher than the impurity concentration in the semiconductor layers 31B in the second regions RB.

The semiconductor layers 31B, 31C disposed at the +Y side of the gate electrode 32 along the Y axis configure one of the drain region and the source region of the thin film transistor 30, and in the present embodiment, configure the drain region 31d. The semiconductor layers 31B, 31C disposed at the -Y side of the gate electrode 32 along the Y axis configure the other of the drain region and the source region of the thin film transistor 30 and, in the present embodiment, configure the source region 31s. That is, impurities are added to the semiconductor layers 31C in the third regions RC at predetermined concentrations required for the drain region and the source region of the thin film transistor 30.

As described above, the impurities are added to the semiconductor layers 31B in the second regions RB at a concentration lower than the predetermined concentration. The semiconductor layer 31B forms an LDD 31l. By disposing the semiconductor layers 31B, the impurity distribution and the electric field in the source-drain diffusion layer are relaxed during the operation of the thin film transistor 30 and thus, the deterioration of the thin film transistor 30 is suppressed.

The fifth conductive layer 125 includes sixth relay electrodes 52. The sixth conductive layer bis formed of a conductive material having a light-blocking property, and includes the data lines 16. The seventh conductive layer 127 includes the common wiring lines 18.

A second dielectric film 63 is disposed between the first conductive layer 121 as the second capacitance electrode 62 and the second conductive layer 122 as the first capacitance electrode 61. A first interlayer insulation layer 71 is disposed between the second conductive layer 122 and the third conductive layer 123. A second interlayer insulation layer 72 is disposed between the third conductive layer 123 and the semiconductor layer 31. A third interlayer insulation layer 73 as a second insulating layer is disposed between the fourth conductive layer 124 and the fifth conductive layer 125. A fourth interlayer insulation layer 74 as a first insulating layer is disposed between the fifth conductive layer 125 and the sixth conductive layer 126. A fifth interlayer insulation layer 75 is disposed between the sixth conductive layer 126 and the seventh conductive layer 127.

As illustrated in FIG. 4B, the capacitive element 60 includes the first capacitance electrode 61 disposed at a side closer to the scanning line 13 along the Z axis, that is, at the +Z side, and the second capacitance electrode 62 disposed at a side closer to the element substrate 111 than the first capacitance electrode 61 along the Z axis, that is, at the -Z side.

As illustrated in FIGS. 4C and 4D, the first capacitance electrode 61 of the capacitive element 60 is electrically coupled to the common wiring line 18 via a first relay electrode 81 provided to the sixth conductive layer 126 and a second relay electrode 82 provided to the fourth conductive layer 124. As illustrated in FIG. 4C, the common wiring line 18 and the second relay electrode 82 are electrically coupled to each other via the first relay electrode 81 disposed in the sixth conductive layer 126. As illustrated in FIG. 4C, the second relay electrode 82 is electrically coupled to an extension portion 61t of the first capacitance electrode 61 of the capacitive element 60. The extension portion 61t is a part of the first capacitance electrode 61.

The sixth relay electrode 52 and the second capacitance electrode 62 of the capacitive element 60 are electrically coupled to the pixel electrode 11 and the drain region 31d of the thin film transistor 30. As illustrated in FIG. 4D, the pixel electrode 11 is electrically coupled to a third relay electrode 83 provided to the seventh conductive layer 127.

As illustrated in FIG. 4C, the third relay electrode 83 is electrically coupled to a fourth relay electrode 84 provided to the sixth conductive layer 126. The fourth relay electrode 84 is electrically coupled to the sixth relay electrode 52. As illustrated in FIG. 4B, the sixth relay electrode 52 is electrically coupled to a fifth relay electrode 85 provided to the fourth conductive layer 124. The fifth relay electrode 85 is electrically coupled to the second capacitance electrode 62 of the capacitive element 60.

In the plan view, the scanning lines 13, the signal wiring lines such as the common wiring lines 18, the thin film transistors 30, and the electrodes such as the first relay electrodes 81 are disposed in the light-blocking region SD that sections the plurality of pixels P. The light-blocking region SD includes linear portions including the scanning lines 13 extending along the X axis and linear portions including the data lines 16 extending along the Y axis, and is disposed in a grid pattern in the plan view. The X axis corresponds to a first axis, and the Y axis corresponds to a second axis.

The sixth interlayer insulation layer (not illustrated) is formed at the seventh conductive layer 127 disposed above the first substrate 10 in the display region E, that is, at the +Z side of the first substrate 10. As illustrated in FIG. 4A, the pixel electrode 11 is provided so as to correspond to each of the plurality of pixels P in the display region E. In the plan view, the pixel electrode 11 is disposed at the sixth interlayer insulation layer 76 in a portion overlapping a part of a region RT sectioned as the pixel P. The region RT is a light-transmissive region that transmits at least a part of the colored light incident on the liquid crystal device 100.

As illustrated in FIG. 4A, the region RT is surrounded by the scanning lines 13, 13 adjacent to each other at an interval along the X axis and the data lines 16, 16 adjacent to each other at an interval along the Y axis, and has a rectangular shape. The width along the X axis of the region RT is larger than at least the width along the X axis of the data line 16. The width along the Y axis of the region RT is larger than at least the width along the Y axis of the scanning line 13, and is equivalent to the width along the X axis of the region RT.

The pixel electrode layer configuring the pixel electrode 11 is disposed in most of the region RT except an end side portion that is located at the +Y side and is parallel to the X axis and an end side portion that is located at the -X side and is parallel to the Y axis, and overlaps an extension portion 83t of the third relay electrode 83 of the pixel P in the plan view. The pixel electrode layer configuring the pixel electrode 11 is disposed on the side wall and the bottom portion of a contact hole formed at the -Y side and in a central portion along the X axis of the region RT in the plan view. The pixel electrode layer is coupled to the extension portion 83t of the third relay electrode 83 of the pixel P with a contact plug CNT11, and is electrically coupled to the third relay electrode 83 of the pixel P. The pixel electrode layer configuring the pixel electrode 11 is formed of a transparent conductor such as ITO.

Although not illustrated, a dummy pixel electrode is disposed so as to correspond to each of the plurality of dummy pixels DP in the dummy pixel region DF in the first peripheral region F1. The dummy pixel electrode is disposed at the sixth interlayer insulation layer 76 in a region overlapping at least a part of the light-transmissive region sectioned as the dummy pixel DP in the plan view. The shape of the dummy pixel electrode in the plan view is substantially the same as the shape of the pixel electrode 11 in the plan view, but may be different from the shape of the pixel electrode 11 in the plan view.

The dummy pixel region DF is sectioned into, for example, a first dummy region, a second dummy region, and a third dummy region from the closest region to the display region E in the X-Y plane. The first dummy region is the region that is adjacent to the display region E and closest to the display region E in the X-Y plane out of the dummy pixel region DF.

The first dummy region includes several tens of dummy pixels DP along the X axis or the Y axis orthogonal to each of the sides of the display region E in the X-Y plane. The dummy pixels DP in the first dummy region have substantially the same structures and component elements as those of the pixels P in the display region E. For example, in the first dummy region, in the light-transmissive region which is surrounded by the scanning lines 13, 13 adjacent to each other and the data lines 16, 16 adjacent to each other in the plan view and can transmit the colored light similarly to the region RT, the seventh conductive layer 127 forming the third relay electrode 83 and the seventh conductive layer 127 forming the common wiring line supplied with a common potential are disposed immediately below the sixth interlayer insulation layer 76, that is, at the fifth interlayer insulation layer 75 disposed at the -Z side. Note that the common wiring line described above may be the same as the common wiring line 18.

In the first dummy region, a dummy pixel electrode layer that configures the dummy pixel electrodes is disposed at a wall surface and a bottom of each of at least a first peripheral region contact hole in the plan view and at the sixth interlayer insulation layer 76 forming a peripheral edge of an opening in the plan view. A first peripheral region contact plug is formed simultaneously with the contact plug CNT11 in the step of forming the contact plug CNT11 in the sixth interlayer insulation layer 76. In the first dummy region, the first peripheral region contact plug is formed, for example, at the -Y side and in the central portion along the X axis of the light-transmissive region of the dummy pixel DP in the plan view. In the first dummy region, the dummy pixel electrode layer includes a portion overlapping the first peripheral region contact plug, the third relay electrode 83, and the common wiring line described above formed in the dummy pixel region DF in the plan view, and is formed in a rectangular frame shape.

In the dummy pixel region DF, the second dummy region is a region that is adjacent to the first dummy region, surrounds the first dummy region, and is disposed at the immediately outer side of the first dummy region in the X-Y plane. The dummy pixel DP is not formed in the second dummy region. In the second dummy region, on the fifth interlayer insulation layer 75, the seventh conductive layer 127 forming the third relay electrodes 83 is not formed, but only the seventh conductive layer 127 forming the common wiring lines is formed.

In the dummy pixel region DF, the third dummy region is a region that is adjacent to the second dummy region in the X-Y plane, surrounds the second dummy region, and is disposed at the outer side of the second dummy region and at the outermost side of the dummy pixel region DF. The dummy pixel DP is not formed in the third dummy region, either. The seventh conductive layer 127 is not formed in the third dummy region on the fifth interlayer insulation layer 75.

In the first dummy region, the dummy pixel electrode layer is electrically coupled to the third relay electrode 83 disposed in the region RT. A video signal of the liquid crystal device 100 is supplied to the dummy pixel electrode layer in the first dummy region. In the second dummy region, the dummy pixel electrode layer is electrically coupled to the common wiring line described above disposed in the light-transmissive region. The common potential in the liquid crystal device 100 is applied to the dummy pixel electrode layer in the second dummy region. In the third dummy region, the dummy pixel electrode layer is not electrically coupled to any wiring line. A floating potential is applied to the dummy pixel electrode layer in the third dummy region.

### Configuration of Thin Film Transistor in Present Embodiment

As described above, the semiconductor layer 31A out of the semiconductor layer 31 constituting the thin film transistor 30 overlaps, in the X-Y plane, the fourth conductive layer 124 which is the gate electrode 32, and is disposed at the -Z side of the fourth conductive layer 124. In the present embodiment, impurities are implanted into a part of the semiconductor layer 31A.

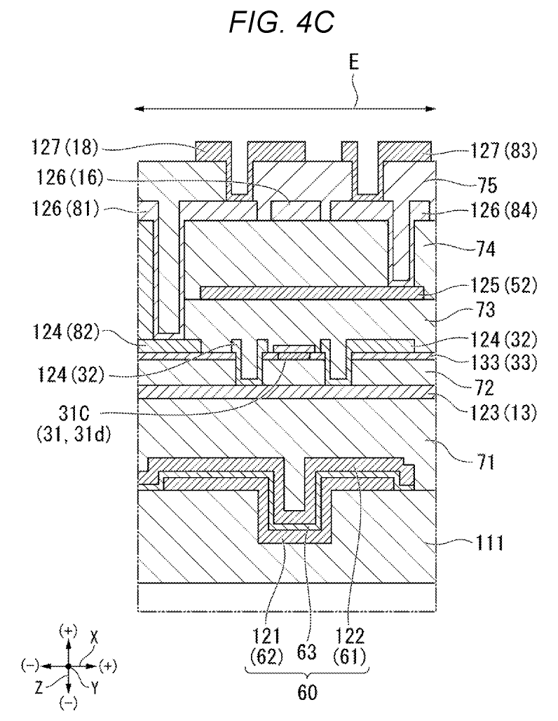

FIG. 5 is a plan view of the semiconductor layer 31 in a first form in the liquid crystal device 100. As illustrated in FIG. 5, the semiconductor layer 31A constituting the channel region in the thin film transistor 30 includes a central region 230, side regions 231, 231, and edge regions 232, 232. The central region 230, the side regions 231, and the edge regions 232 each have a rectangular shape in the plan view.

The width w230 along the Y axis of the central region 230 is not particularly limited, but is smaller than at least the dimension, that is, the width along the Y axis of the semiconductor layers 31B, 31C , and is, for example, no smaller than 0.30 μm. The length t230 along the X axis of the central region 230 is not particularly limited, but is larger than at least the width w230 along the Y axis and smaller than the length t31 along the X axis of the semiconductor layers 31B, 31C.

In the plan view, the side regions 231, 231 are formed at the -Y side and the +Y side of the central region 230 and are adjacent to the central region 230 along the Y axis. The width w231 along the Y axis of the side region 231 is not particularly limited, but is, for example, no smaller than 0.30 μm. However, the total width w240 along the Y axis of the side region 231 at the -Y side, the central region 230, and the side region 231 at the +Y side is equivalent to or no smaller than the width w124 along the Y axis of the fourth conductive layer 124. The length t231 along the X axis of the side region 231 is equivalent to the length t230 along the X axis of the central region 230. In the plan view, the central region 230, the side regions 231, 231, and the edge region 232 overlap the fourth conductive layer 124.

The edge regions 232 are formed at the -X side and the +X side of the central region 230 and the side regions 231, 231, and are adjacent to each of the central region 230 and the side regions 231, 231 along the X axis.

The width w232 along the Y axis of the edge region 232 is larger than the total width w240 along the Y axis of the central region 230 and the side regions 231, 231 and is larger than the width w124 along the Y axis of the fourth conductive layer 124. A dimension, that is, a distance by which the edge region 232 further extends toward the -Y side beyond the side region 231 at the -Y side and the fourth conductive layer 124 is not particularly limited, but is, for example, about 0.25 μm. A distance by which the edge region 232 further extends toward the +Y side beyond the side region 231 at the +Y side and the fourth conductive layer 124 is equivalent to the distance by which the edge region 232 extends toward the -Y side. By the width w232 of the edge regions 232 being larger than the width of both ends along the Y axis of the side regions 231, 231 and the width w124 of the fourth conductive layer 124, the edge regions 232 extending toward the -Y side beyond the side region 231 at the -Y side, and the edge regions 232 extending toward the +Y side beyond the side region 231 at the +Y side, the impurity as the channel dope implanted into the edge regions 232 is reliably diffused within the range along the Y axis of the side regions 231, 231 and the range along the Y axis of the fourth conductive layer 124, and the effect of enhancing the threshold voltage Vth is enhanced as described later.

The length t232 along the X axis of the edge regions 232 is not particularly limited, but is smaller than at least the length t230 of the central region 230 and the length t231 of the side regions 231, smaller than the width w232 along the Y axis of the edge regions 232, and is, for example, about 1.0 μm.

A long side at the -X side parallel to the Y axis of the edge region 232 at the -X side is located at the -X side of long sides at the -X side parallel to the Y axis of the semiconductor layers 31B, 31C. A long side at the +X side parallel to the Y axis of the edge region 232 at the +X side is located at the +X side of long sides at the +X side parallel to the Y axis of the semiconductor layers 31B, 31C.

The thin film transistor 30 is of, for example, the n-type. An additive implanted into the semiconductor layer 31A is, for example, boron. In the semiconductor layer 31A, the impurity concentration in each of the side regions 231 and the edge regions 232 is higher than the impurity concentration in the central region 230. That is, the side regions 231, 231 represent regions at the -Y side and the +Y side different in concentration of the impurity as the channel dope from the central region along the Y axis in the region overlapping the semiconductor layers 31B, 31C along the X axis out of the semiconductor layer 31A constituting the channel region of the thin film transistor 30. In the semiconductor layer 31 of the first form, the side regions 231, 231 represent regions at the -Y side and the +Y side higher in concentration of the impurity as the channel dope than the central region along the Y axis, and represent regions at the -Y side and the +Y side higher in concentration of the impurity than the central region 230, in the region overlapping the semiconductor layers 31B, 31C along the X axis out of the semiconductor layer 31A.

The impurity concentration in each of the side regions 231 and the edge regions 232 is no lower than, for example, a ratio of 1.2, and is about 0.2 times that when the impurity is implanted into the entire semiconductor layer 31A having a rectangular shape as in the related art. In the manufacturing process of the liquid crystal device 100, a resist layer (not illustrated) is provided as a mask in the central region 230, and the impurities are implanted into the side regions 231, 231 and the edge regions 232, 232 other than the central region 230. The impurity concentration in the central region 230 is preferably zero, but in some cases a ratio of 0 to 0.3 may occur due to a thermal diffusion treatment in a subsequent step in the element substrate 111. When the impurity concentration in the central region 230 is zero, the semiconductor layer 31A in the central region 230 is made of an intrinsic semiconductor.

The top-gate structure and the LDD structure are adopted in the thin film transistor 30. The side region 231 is an LDD region adjacent to the semiconductor layer 31B at an opposite side to the central region 230 along the Y axis. In the plan view, corners of the semiconductor layer 31B at the -X side and +X side located at a side adjacent to the side region 231 overlap the edge regions 232 of the semiconductor layer 31A. When the liquid crystal device 100 is manufactured, in the edge region 232, a defect BL occurs at a position forming a substantially straight line with the long sides, that is, the end sides at the -X side parallel to the Y axis of the semiconductor layers 31B, 31C, or with the long sides, that is, the end sides at the +X side, and may act as an edge transistor.

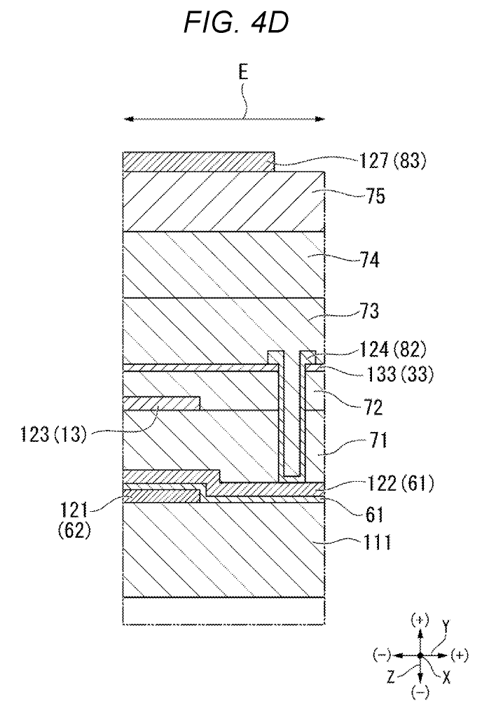

FIG. 6 is a schematic graph showing hump characteristics of the thin film transistor 30. The horizontal axis of the graph in FIG. 6 represents the gate voltage, and represents, for example, the voltage applied to the fourth conductive layer 124 as the gate electrode 32. The vertical axis of the graph in FIG. 6 represents the drain current, and represents, for example, the current obtained from the semiconductor layers 31B, 31C as the drain region 31d disposed at the +Y side of the gate electrode 32.

In the thin film transistor 30 including the semiconductor layer 31A of the first form of the present embodiment, since the impurity as the channel dope is not added to the central region 230, the impurity concentration in the edge regions 232 along the X axis is higher than an effective impurity concentration in a central portion 240 including the central region 230 and the side regions 231 of the semiconductor layer 31A. Since the impurity concentration in the edge regions 232 corresponding to end portions of the semiconductor layer 31A in the first form is higher than the impurity concentration in the central region 230 and the side regions 231 corresponding to the central portion 240 of the semiconductor layer 31A in the first form, the threshold voltage Vth represented by the hump characteristics of the thin film transistor 30 is shifted to "Enhance". Since the impurity concentration in the central region 230 and the side regions 231 is lower than the impurity concentration in the edge regions 232, the threshold voltage Vth of the thin film transistor 30 is shifted to "Depression". The impurity concentration in the side regions 231 is appropriately set in consideration of the impurity concentration in the edge regions 232 in accordance with an adjustment amount of the threshold voltage Vth. In the thin film transistor 30 having the semiconductor layer 31A in the first form, a decrease in the drain current Ion when the thin film transistor 30 is controlled at a voltage no lower than the threshold voltage Vth is suppressed, and the switching characteristics of the thin film transistor 30 are improved.

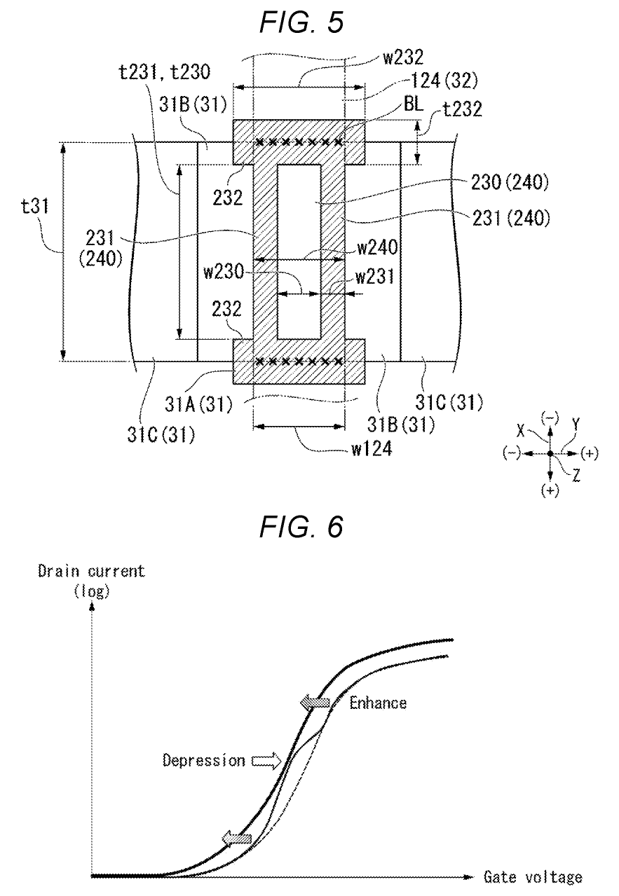

FIG. 7 is a plan view of the semiconductor layer 31 of a second form in the liquid crystal device 100. As shown in FIG. 7, the semiconductor layer 31A of the second form is configured similarly to the semiconductor layer 31A described above, and includes the central region 230, the side regions 231, 231, and the edge regions 232, 232. The central region 230, the side regions 231, and the edge regions 232 each have a rectangular shape in the plan view. However, in the semiconductor layer 31 of the second form, the impurity concentration in each of the central region 230 and the edge regions 232 is higher than the impurity concentration in the side regions 231. The impurity concentration in the side regions 231 is preferably zero, but a ratio of 0 to 0.3 may occur in some cases due to a thermal diffusion treatment in a subsequent step in the element substrate 111. When the impurity concentration in the side regions 231 is zero, the semiconductor layer 31A in the side regions 231 is made of an intrinsic semiconductor.

In the semiconductor layer 31 of the second form, the side regions 231, 231 represent regions at the -Y side and the +Y side lower in concentration of the impurity as the channel dope than the central region along the Y axis, and represent regions at the -Y side and the +Y side lower in concentration of the impurity than the central region 230, in the region overlapping the semiconductor layers 31B, 31C along the X axis out of the semiconductor layer 31A.

Also in the thin film transistor 30 having the semiconductor layer 31A of the second form of the present embodiment, similarly to the thin film transistor 30 having the semiconductor layer 31A of the first form, since the impurity concentration in the edge regions 232 is higher than the impurity concentration in the central region 230 and the side regions 231, the threshold voltage Vth represented by the hump characteristics of the thin film transistor 30 is shifted to "Enhance". Since the impurity concentration in the central region 230 and the side regions 231 is lower than the impurity concentration in the edge regions 232, the threshold voltage Vth of the thin film transistor 30 is shifted to "Depression". As a result, the switching characteristics of the thin film transistor 30 are improved.

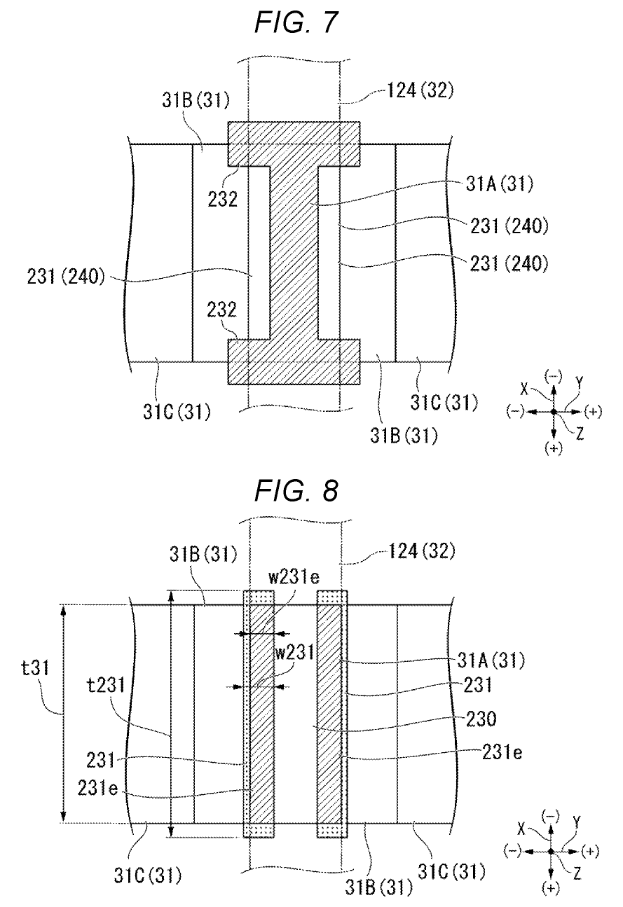

FIG. 8 is a plan view of the semiconductor layer 31 of a third form in the liquid crystal device 100. As shown in FIG. 8, the semiconductor layer 31A of the third form has the central region 230 and the side regions 231, 231, but does not have the edge regions 232, 232 unlike the semiconductor layer 31A of the first form and the second form. In the semiconductor layer 31A of the third form, the width w231 along the Y axis of the side region 231 is not particularly limited, but is larger than the width w231 of the side region 231 of the semiconductor layer 31A of the first form and the second form, and is, for example, no smaller than 0.60 μm. The total width along the Y axis of the side region 231 at the -Y side, the central region 230, and the side region 231 at the +Y side is larger than the width w124 along the Y axis of the fourth conductive layer 124. In the semiconductor layer 31A of the third form, the length t231 along the X axis of the side regions 231 is larger than the length t230 along the X axis of the central region 230. In the semiconductor layer 31 of the third form, the impurity concentration in the side regions 231 is higher than the impurity concentration in the central region 230. The impurity concentration in the central region 230 is preferably zero, but a ratio of 0 to 0.3 may occur in some cases due to a thermal diffusion treatment in a subsequent step in the element substrate 111. When the impurity concentration in the central region 230 is zero, the semiconductor layer 31A in the central region 230 is made of an intrinsic semiconductor.

In the semiconductor layer 31 of the third form, the side regions 231, 231 represent regions at the -Y side and the +Y side higher in concentration of the impurity as the channel dope than the central region along the Y axis, and represent regions at the -Y side and the +Y side higher in concentration of the impurity than the central region 230, in the region overlapping the semiconductor layers 31B, 31C along the X axis out of the semiconductor layer 31A.

Since the width w231 along the Y axis of the side regions 231 is larger than the width w231ealong the Y axis of a side region 231e that overlaps the fourth conductive layer 124 in the plan view, and the distance along the Y axis from an end at the -Y side of the side region 231 at the -Y side to an end at the +Y side of the side region 231 at the +Y side is larger than the width w124 along the Y axis of the fourth conductive layer 124, the impurity as the channel dope implanted into the side region 231 is reliably diffused into the range of the side region 231e and the range along the Y axis that overlaps the fourth conductive layer 124 in the plan view, and the effect of enhancing the threshold voltage Vth is enhanced. In particular, when the thin film transistor 30 has the p-type MOS structure and the impurity that is channel-doped in the semiconductor layer 31A is an impurity such as phosphorus, the effect described above is favorably obtained.

### First Aspect

Examples of the thin film transistor 30 of a first aspect include the p-type MOS structure. In the semiconductor layer 31 of the first form described above or the semiconductor layer 31 of the second form described above, an impurity such as phosphorus or fluorine (F) is added only to a predetermined region of the semiconductor layer 31A, and an impurity such as boron or arsenic (As) is added to the semiconductor layers 31B, 31C.

In the p-type thin film transistor 30, by adopting a configuration in which a region in which an impurity such as phosphorus is diffused is formed in an O-shape or a rectangular shape in the plan view as shown in FIG. 5, it is possible to realize a substantially constant threshold voltage Vth regardless of the doping amount of the impurity, and to increase the mobility of carriers in the semiconductor layer 31. A dark current as the p-type thin film transistor 30 used in a complementary metal oxide semiconductor (CMOS) circuit, that is, a drain current Ioff in the OFF state is stabilized, and a low output level is ensured. This is based on a mechanism in which the polarity of the semiconductor layer 31A at the -Z side in the fourth conductive layer 124 and in the central portion along the Y axis is reversed from the polarity of the semiconductor layers 31B, 31C in the peripheral portion, and the OFF state and the threshold voltage Vth can be controlled by the performance when the semiconductor layers 31B, 31C are activated.

### Second Aspect

Examples of the thin film transistor 30 of a second aspect include the n-type MOS structure. In the semiconductor layer 31 of the first form described above or the semiconductor layer 31 of the second form described above, an impurity such as boron or arsenic is added only to a predetermined region of the semiconductor layer 31A, and an impurity such as phosphorus or fluorine is added to the semiconductor layers 31B, 31C.

In the n-type thin film transistor 30, by adopting the configuration in which the region in which the impurity such as boron is diffused is formed in an I-shape in the plan view as illustrated in FIG. 7, the impurity is not added to the side regions 231 of the semiconductor layer 31A located between the central region 230 of the semiconductor layer 31A and the semiconductor layer 31B as the LDD region. Therefore, the polarity of the semiconductor layer 31 is easily reversed, and the activation in the semiconductor layer 31 is promoted. As a result, in the semiconductor layer 31, activation of impurities such as boron in the central region 230 of the semiconductor layer 31A is dominant, the threshold voltage Vth is likely to change, humping of the hump characteristics is reduced, and switching characteristics in the ON state are improved.

### Third Aspect

Examples of the thin film transistor 30 of a third aspect include the p-type MOS structure. In the semiconductor layer 31 of the third form described above, an impurity such as phosphorus or fluorine is added only to a predetermined region of the semiconductor layer 31A, that is, the side regions 231, 231, and an impurity such as boron or arsenic is added to the semiconductor layers 31B, 31C.

In the p-type thin film transistor 30, by adopting the configuration in which the two side regions 231 are formed along the X axis with the central region 230 interposed therebetween in the plan view with the regions in which the impurity such as phosphorus is diffused as illustrated in FIG. 8, the substantially constant threshold voltage Vth is realized regardless of the doping amount of the impurity, the drain current Ioff is stabilized, and a low output level is ensured, similarly to the first aspect.

### Modified Examples of First to Third Aspects

Note that in the thin film transistor 30 according to any one of the first to third aspects, the semiconductor layer 31 may be configured with the semiconductor layers 31A, 31C with the semiconductor layer 31B not provided to the semiconductor layer 31. In this case, in the semiconductor layer 31, the semiconductor layer 31C is formed so as to be adjacent to the semiconductor layer 31A at the -Y side and the +Y side of the semiconductor layer 31A.

### Fourth Aspect

In the first aspect and the second aspect described above, after the impurity is implanted into the semiconductor layer 31A, the semiconductor layer 31A may be subjected to a heat treatment at 800° C or higher before the fourth conductive layer 124, a polycrystalline silicon layer into which an impurity such as phosphorus is implanted, or the like is formed at the +Z side of the semiconductor layer 31A. The width along the Y axis of an opening of a resist layer or the like (not illustrated) as a mask used when implanting impurities in the semiconductor layer 31A is smaller than the width w124 along the Y axis of the fourth conductive layer 124 as the gate electrode 32. Therefore, after the steps of patterning and lithography for forming openings in the resist layer, a cleaning treatment using oxygen (O₂) is performed, and after a scum layer of the resist is removed, the impurities are implanted into only a predetermined region of the semiconductor layer 31A.

In order to promote the activation of the impurity, it is preferable that after the impurity is implanted into only a predetermined region of the semiconductor layer 31A, the heat treatment at 800° C or higher is performed a plurality of times, and finally the heat treatment at 1000° C to 1100° C is performed. By performing the heat treatment on the semiconductor layer 31A after the impurity is implanted, diffusion of the impurity from the semiconductor layer 31A through the insulating film 133 which is the gate insulating film 33 is prevented, and a decrease in controllability and reliability of the gate potential is suppressed. As a result, the switching characteristics of the thin film transistor 30 are improved.

Note that it is conceivable that a light leakage current in the pixel P is related to a depletion layer in the semiconductor layer 31 of the thin film transistor 30. It is conceivable that an amount of the light leakage current depends on the size of the region of the depletion layer in the semiconductor layer 31. In the boundary portion between the semiconductor layers 31A, 31B of the thin film transistor 30, the n-type impurity and the p-type impurity coexist, and the light leakage current may vary among the plurality of pixels P. By the heat treatment on the semiconductor layer 31A, the impurity is activated, the region of the depletion layer is reduced, and the variation in the light leakage current among the plurality of pixels P is suppressed.

The length t31 along the X axis of the semiconductor layer 31 of the thin film transistor 30 of the pixel P is, for example, about 1 μm or less, which is very short. In order to manufacture the structure shown in FIG. 7, the semiconductor layers 31, 31A of the second form in which the impurity implantation region including the central region 230 and the edge regions 232, 232 is formed in an I-shape in the plan view has to be selected due to design constraints. In the manufacture of the semiconductor layer 31 of the second form, a depletion layer can be intentionally and easily formed in the semiconductor layers 31B, 31C constituting the source region 31s and the drain region 31d by forming an intrinsic semiconductor into which no impurity is implanted. As a result, the light leakage current increases even in a state where, for example, a low voltage of about 4 V in a minus field is applied to a common potential of about 7 V. In this case, in a state where a high voltage of 10 V in the plus field is applied, an effect of alleviating an increase in light leakage current is expected. In addition, an effect of suppressing the variation in light leakage current depending on the gate voltage in the OFF state is expected. As a result, the unevenness of the light leakage current in the liquid crystal device 100 and the projection flicker of the image light emitted from the liquid crystal device 100 are suppressed, and thus, the display quality is improved.

### Test Production of Thin Film Transistor

The disclosers of the present application experimentally produced the n-type thin film transistor 30 suitable for the liquid crystal device 100, and confirmed the operation and performance. In the present test production, as shown in FIG. 7, the configuration of the semiconductor layer 31A of the second form in which the impurity diffusion region is formed in the I-shape in the plan view was adopted. Impurities were implanted into the semiconductor layer 31A, and a heat treatment, that is, an activation treatment was performed three times under a temperature environment of 1000° C. As a result, the decrease in the drain current Ion when the thin film transistor 30 experimentally produced was controlled at a voltage no lower than the threshold voltage Vth was suppressed to 1/3 compared to when the impurity was added to the entire surface of the semiconductor layer 31A. Since the controllability of the threshold voltage Vth and the effect of suppressing the decrease in the drain current Ion were obtained, it is conceivable that the process margin of the liquid crystal device 100 is improved. The drain-source voltage Vds of the thin film transistor 30 experimentally produced was 10 V.

When the dose amount of the impurity added to the central region 230 and the edge regions 232 of the semiconductor layer 31A of the thin film transistor 30 experimentally produced was set to 1.2 times to 1.3 times the dose amount of the impurity when added to the entire surface of the semiconductor layer 31A as in the related art, humping of the hump characteristics was favorably suppressed, and the threshold voltage Vth was equivalent to that in the related art as a result. From this result, it is conceivable that the dose amount of the impurity added to the central region 230 and the edge regions 232 of the semiconductor layer 31A is preferably at least 1.2 times or more the dose amount of the impurity added to the entire surface of the semiconductor layer 31A.

The disclosers of the present application experimentally produced the p-type thin film transistor 30 suitable for the liquid crystal device 100, and confirmed the operation and performance. In the present test production, as shown in FIG. 5, the configuration of the semiconductor layer 31A of the first form in which the impurity diffusion region is formed in the O-shape in the plan view was adopted. When the impurity was added to the entire surface of the semiconductor layer 31A, the threshold voltage Vth changed when the dose amount of the impurity was changed in three types. When the dose amount of the impurity added only to the central region 230 and the edge regions 232 of the semiconductor layer 31A was changed in three types as in the present embodiment, the threshold voltage Vth hardly changed, the drain current Ion in the ON state slightly increased, the drain current Ioff in the OFF state decreased, the switching characteristics were stabilized, and the switching characteristics were improved compared to when the impurity was added to the entire surface of the semiconductor layer 31A.

In the n-type or p-type thin film transistor 30 experimentally produced by the disclosers of the present application, the drain current Ioff in the OFF state was suppressed by performing the heat treatment on the thin film transistor 30 at, for example, 1050° C for 10 minutes, and the characteristics were improved by 50% or more compared to when the heat treatment was not performed.

### Electronic Apparatus

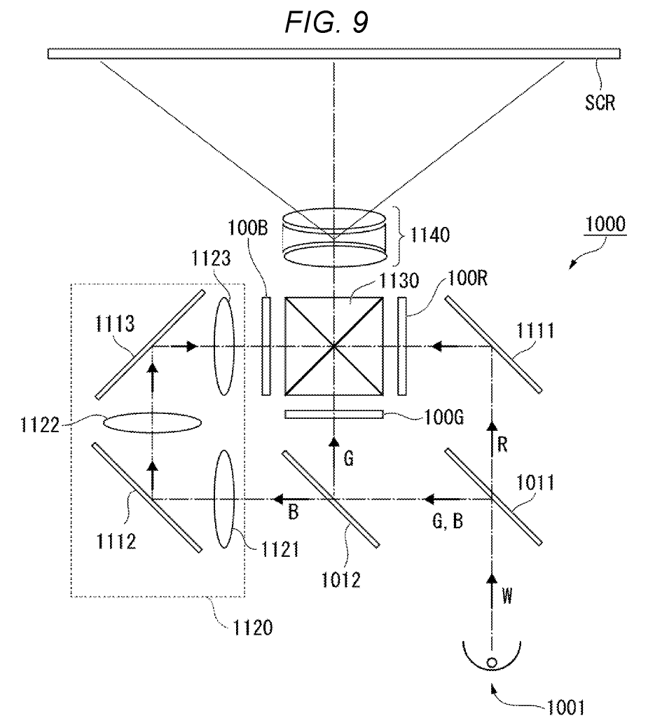

In the present embodiment, the description will be presented citing a projector 1000 as an example of an electronic apparatus including the liquid crystal device 100. FIG. 9 is a schematic diagram of the projector 1000. As illustrated in FIG. 9, the projector 1000 includes a light source device 1001, dichroic mirrors 1011, 1012, liquid crystal devices 100B, 100G, and 100R, reflection mirrors 1111, 1112, and 1113, relay lenses 1121, 1122, and 1123, a cross dichroic prism 1130, and a projection optical system 1140.

The light source device 1001 emits white light W. The light source device 1001 is, for example, a discharge type lamp unit, but may be a light emitting diode, a laser, or the like or may be a device in which a light emitter that emits blue light and a phosphor that converts a part of the blue light emitted from the light emitter into yellow light and emits the yellow light are combined to each other, and is not limited to a specific light source device.

The white light W emitted from the light source device 1001 is separated by the two dichroic mirrors 1011, 1012 into colored light of three colors different in wavelength range from each other. The colored light of the three colors include red light R, green light G, and blue light B. The dichroic mirror 1011 transmits the red light R and reflects the green light G and the blue light B shorter in wavelength than the red light R. The red light R transmitted through the dichroic mirror 1011 is reflected by the reflection mirror 1111 and enters the liquid crystal device 100R. The green light G reflected by the dichroic mirror 1011 is reflected by the dichroic mirror 1012 and then enters the liquid crystal device 100G. The blue light B reflected by the dichroic mirror 1011 is transmitted through the dichroic mirror 1012 and is emitted to a relay lens system 1120.

The relay lens system 1120 includes the relay lenses 1121, 1122, and 1123 and the reflection mirrors 1112 and 1113. The optical path of the blue light B from the dichroic mirror 1011 to the liquid crystal device 100B is longer than the optical path of the green light G from the dichroic mirror 1011 to the liquid crystal device 100G and the optical path of the red light R from the dichroic mirror 1011 to the liquid crystal device 100R. Therefore, the luminous flux of the blue light B tends to be larger than the luminous fluxes of the green light G and the red light R. By using the relay lens 1122, the expansion of the luminous flux of the blue light B is suppressed. The blue light B incident on the relay lens system 1120 is reflected by the reflection mirror 1112 and converged in the vicinity of the relay lens 1122 by the relay lens 1121. The blue light B enters the liquid crystal device 100B through the reflection mirror 1113 and the relay lens 1123.

The liquid crystal devices 100R, 100G, and 100B are light modulation devices in the projector 1000. The liquid crystal device 100 described above is applied to the liquid crystal devices 100R, 100G, and 100B.

Each of the liquid crystal devices 100R, 100G, and 100B is electrically coupled to an external control device of the projector 1000. An image signal that designates the gradation level of each of the red light R, the green light G, and the blue light B is supplied from the external control device for each colored light, and is processed by an integrated circuit attached to each of the liquid crystal devices 100R, 100G, and 100B. The liquid crystal devices 100R, 100G, and 100B are driven in accordance with the image signals received from the respective integrated circuits. The liquid crystal device 100R modulates the red light R incident thereon. The liquid crystal device 100G modulates the green light G incident thereon. The liquid crystal device 100B modulates the blue light B incident thereon.

The red light R, the green light G, and the blue light B modulated by the liquid crystal devices 100R, 100G, and 100B enter the cross dichroic prism 1130 from three directions. The cross dichroic prism 1130 is a color combining optical system in the projector 1000 and combines the red light R, the green light G, and the blue light B incident thereon. In the cross dichroic prism 1130, the red light R and the blue light B are reflected by 90 degrees with respect to the respective incident directions, and the green light G is transmitted. As a result, the red light R, the green light G, and the blue light B combined with each other are emitted in the same direction. The red light R, the green light G, and the blue light B are combined as a display light for displaying a color image, and emitted from the cross dichroic prism 1130 toward the projection optical system 1140.

The projection optical system 1140 is disposed so as to face to the outside of the projector 1000. The display light is emitted via the projection optical system 1140 in an enlarged manner, and is projected onto a screen SCR as a projection target.

### Functions and Advantages

The liquid crystal device (electro-optic device) 100 of the present embodiment described above includes the thin film transistor (transistor) 30 disposed on the element substrate (substrate) 111 of the first substrate 10, that is, at the +Z side. The thin film transistor 30 includes a semiconductor layer 31 and the fourth conductive layer 124 as the gate electrode 32. The semiconductor layer 31 includes a semiconductor layer 31A forming the channel region, the semiconductor layers 31B, 31C forming the source region 31s, and the semiconductor layers 31B, 31C forming the drain region 31d, and extends along the Y axis (first direction). The semiconductor layers 31B, 31Cforming the source region 31s are disposed at the -Y side of the semiconductor layer 31A and the fourth conductive layer 124. The semiconductor layers 31B, 31C forming the drain region 31d are disposed at the +Y side of the semiconductor layer 31A and the fourth conductive layer 124. The fourth conductive layer 124 faces the semiconductor layer 31A, which is the channel region, via the insulating film 133, which is the gate insulating film 33, along the Z axis. An impurity according to the type and conductivity of the thin film transistor 30 is added to only a part of the semiconductor layer 31A forming the channel region. In the liquid crystal device 100 of the present embodiment, the impurity concentration in the central region 230 of the semiconductor layer 31A, which is the channel region of the thin film transistor 30, and the impurity concentration in each of the side regions 231, 231 at both sides of the central region 230 are different from each other along the Y axis.

In the liquid crystal device 100 of the present embodiment, the hump characteristics, the threshold voltage Vth, and the drain current Ion in the ON state and the OFF state of the thin film transistor 30 can be adjusted by making the impurity concentration in the central region 230 and the impurity concentration in the side regions 231 of the semiconductor layer 31A different from each other. In the liquid crystal device 100 of the present embodiment, the sheet resistance of the low concentration region of the impurity in the semiconductor layer 31A can be reduced. According to the liquid crystal device 100 of the present embodiment, the switching characteristics of the thin film transistor 30 can be controlled in accordance with the type and conductivity of the thin film transistor 30, the threshold voltage Vth can be stabilized, the drain current Ion in the ON state can be increased, or the drain current Ioff in the OFF state can be decreased, and as a result, the switching characteristics of the thin film transistor 30 can be improved.

In the liquid crystal device 100 of the present embodiment, the impurity concentration in the side regions 231 of the semiconductor layer 31A in the channel region of the semiconductor layer 31 is higher than the impurity concentration in the central region 230. In the semiconductor layer 31 of the first form described above, the region into which the impurity as the channel dope is implanted is a region occupied by the two side regions 231, 231 and the two edge regions 232, 232, and the region into which the impurity as the channel dope is implanted has an O-shape or a rectangular shape in the plan view. When the impurity as the channel dope is implanted into the side regions 231, 231 and the edge regions 232, 232, a mask (not illustrated) that matches the shape of the impurity region having the O-shape or the rectangular shape is used. In the semiconductor layer 31 of the second form described above, the region into which the impurity as the channel dope is implanted is the region occupied by the central region 230 and the two edge regions 232, 232, and the region into which the impurity as the channel dope is implanted has an I-shape in the plan view. When the impurity as the channel dope is implanted into the central region 230 and the edge regions 232, 232, a mask (not illustrated) that matches the shape of the impurity region having the I-shape is used. In the semiconductor layer 31 of the third form described above, the region into which the impurity as the channel dope is implanted is the region occupied by the two side regions 231, 231, and the region into which the impurity as the channel dope is implanted has two linear shapes extending along the X axis at an interval from each other along the Y axis in the plan view. When the impurity as the channel dope is implanted into the side regions 231, 231, a mask (not shown) that matches the shapes of the impurity region having the two linear shapes is used.

In the liquid crystal device 100 of the present embodiment, since the impurity concentration in the side regions 231 is higher than the impurity concentration in the central region 230 along the Y axis, it is possible to appropriately shift the threshold voltage Vth of the thin film transistor 30 to "Enhance" or "Depression", suppress the hump, and improve the switching characteristics of the thin film transistor 30.

In the liquid crystal device 100 of the present embodiment, the impurity concentration in the central region 230 of the semiconductor layer 31A is preferably zero.

In the liquid crystal device 100 of the present embodiment, when no impurity is implanted into the central region 230 of the semiconductor layer 31A and the central region 230 is an intrinsic semiconductor, the controllability of the switching characteristics described above of the thin film transistor 30 is enhanced, and the switching characteristics of the thin film transistor 30 can be further improved.

In the liquid crystal device 100 of the present embodiment, the thin film transistor 30 has, for example, the p-type MOS structure. The fourth conductive layer 124 that is the gate electrode 32 extends along the X axis (second direction) orthogonal to the Y axis and the Z axis parallel to the thickness direction of the element substrate 111. In this case, the dimension along the Y axis of the semiconductor layer 31A in the channel region is no smaller than the dimension along the Y axis of the fourth conductive layer 124.

In the liquid crystal device 100 of the present embodiment, as described above, the thin film transistor 30 has the p-type MOS structure, the side region 231 of the semiconductor layer 31A overlaps at least the fourth conductive layer 124 along the Y axis, and may extend toward the -Y side and the +Y side beyond the fourth conductive layer 124. According to the liquid crystal device 100 of the present embodiment, it is possible to appropriately shift the threshold voltage Vth of the thin film transistor 30 having the p-type MOS structure to "Enhance" or "Depression", suppress the hump, and improve the switching characteristics of the thin film transistor 30 having the p-type MOS structure.

In the liquid crystal device 100 of the present embodiment, in the X axis (second direction) orthogonal to the Y axis and the Z axis parallel to the thickness direction of the element substrate 111, the semiconductor layer 31A which is the channel region of the thin film transistor 30 has the central portion 240 including the central region 230 and the side regions 231, 231, and the edge regions 232 at both sides of the central portion 240. The impurity concentration in the edge regions 232 is higher than the impurity concentration in the central portion 240.

In the liquid crystal device 100 of the present embodiment, since the impurity concentration in the edge regions 232 is higher than the impurity concentration in at least the central region 230 of the central portion 240 and is higher than the effective impurity concentration in the central portion 240 including the side regions 231, 231, the threshold voltage Vth represented by the hump characteristics of the thin film transistor 30 can be shifted to "Enhance". Meanwhile, since the impurity concentration in the central portion 240 is lower than the impurity concentration in the edge regions 232, the threshold voltage Vth of the thin film transistor 30 can be shifted to "Depression". According to the liquid crystal device 100 of the present embodiment, the impurity concentration in the side regions 231 of the central portion 240 and the impurity concentration in the edge regions 232 can be adjusted, the threshold voltage Vth of the thin film transistor 30 can appropriately be shifted to "Enhance" or "Depression", suppress the hump, and the switching characteristics of the thin film transistor 30 can be improved compared to the related-art electro-optic device.

In the liquid crystal device 100 of the present embodiment, the dimension along the Y axis of the edge region 232 is larger than the dimension along the Y axis of the central portion 240.

In the liquid crystal device 100 according to the present embodiment, the impurity implanted into the edge regions 232 can be diffused at least within a range from the end at the -Y side of the side region 231 at the -Y side of the central portion 240 to the end at the +Y side of the side region 231 at the +Y side along the Y axis, the threshold voltage Vth of the thin film transistor 30 can be reliably shifted to "Enhance", and the hump characteristics can be enhanced.

In the liquid crystal device 100 of the present embodiment, the thin film transistor 30 has, for example, the p-type MOS structure. The fourth conductive layer 124, which is the gate electrode 32, extends along the X axis. The impurity concentration in the side regions 231 of the semiconductor layer 31A in the channel region is higher than the impurity concentration in the central region 230, and is equivalent to the impurity concentration in, for example, the edge regions 232. The dimension along the Y axis of the central portion 240 of the semiconductor layer 31A is equivalent to the dimension along the Y axis of the fourth conductive layer 124.

In the liquid crystal device 100 of the present embodiment, as described above, the thin film transistor 30 has the p-type MOS structure, and the central portion 240 of the semiconductor layer 31A overlaps the fourth conductive layer 124 along the Y axis. In the semiconductor layer 31A, a region to which the impurity as the channel dope is added is formed in the O-shape or the rectangular shape in the plan view. According to the liquid crystal device 100 of the present embodiment, it is possible to appropriately shift the threshold voltage Vth of the thin film transistor 30 having the p-type MOS structure to "Enhance" or "Depression", suppress the hump, and improve the controllability of the switching characteristics of the thin film transistor 30 having the p-type MOS structure.

Also in the liquid crystal device 100 described above of the present embodiment, the impurity concentration in the central region 230 of the semiconductor layer 31A is preferably zero.

In the liquid crystal device 100 of the present embodiment, when no impurity is implanted into the central region 230 of the semiconductor layer 31A and the central region 230 is an intrinsic semiconductor, the switching characteristics of the thin film transistor 30 having the p-type MOS structure described above can be further improved.

In the liquid crystal device 100 of the present embodiment, the thin film transistor 30 has, for example, the n-type MOS structure. The fourth conductive layer 124, which is the gate electrode 32, extends along the X axis. The impurity concentration in the central region 230 of the semiconductor layer 31A in the channel region is higher than the impurity concentration in the side regions 231, and is, for example, equivalent to the impurity concentration in the edge regions 232. The dimension along the Y axis of the central portion 240 of the semiconductor layer 31A is equivalent to the dimension along the Y axis of the fourth conductive layer 124.

In the liquid crystal device 100 of the present embodiment, as described above, the thin film transistor 30 has the n-type MOS structure, and the central portion 240 of the semiconductor layer 31A overlaps the fourth conductive layer 124 along the Y axis. In the semiconductor layer 31A, a region to which the impurity as the channel dope is added is formed in the I-shape in the plan view. According to the liquid crystal device 100 of the present embodiment, it is possible to appropriately shift the threshold voltage Vth of the thin film transistor 30 having the n-type MOS structure to "Enhance" or "Depression", suppress the hump, and improve the controllability of the switching characteristics of the thin film transistor 30 having the n-type MOS structure.

In the liquid crystal device 100 described above of the present embodiment, the impurity concentration in the side regions 231, 231 of the semiconductor layer 31A is preferably zero.

In the liquid crystal device 100 of the present embodiment, when no impurity is implanted into the side regions 231, 231 of the semiconductor layer 31A and the side regions 231, 231 are intrinsic semiconductors, the switching characteristics of the thin film transistor 30 having the n-type MOS structure described above can be further improved.

In the liquid crystal device 100 described above of the present embodiment, the length t31 along the X axis of the semiconductor layer 31 is 1 μm or less.

In the liquid crystal device 100 of the present embodiment, a depletion layer can be intentionally and easily formed in the semiconductor layers 31B, 31C forming the source region 31s and the drain region 31d. This alleviates the increase in the light leakage current, and suppresses the variation in the light leakage current depending on the gate voltage in the OFF state. According to the liquid crystal device 100 of the present embodiment, it is possible to suppress the unevenness of the light leakage current in the liquid crystal device 100 and the projection flicker of the image light emitted from the liquid crystal device 100 to thereby improve the display quality.

In the liquid crystal device 100 described above of the present embodiment, after the impurity is added to a part of the semiconductor layer 31A in the channel region, the heat treatment is performed a plurality of times at 800° C or higher.

According to the liquid crystal device 100 of the present embodiment, after the impurity as the channel dope is implanted into the semiconductor layer 31A, the heat treatment is performed a plurality of times at 800° C or higher, and thus, the insulating film 133 as the gate insulating film 33 can be baked, the impurities of the semiconductor layer 31A in the channel region of the thin film transistor 30 can sufficiently be activated, and the impurities can be prevented from diffusing to an unexpected region through the insulating film 133. As a result, the switching characteristics including switching between the ON state and the OFF state of the thin film transistor 30 can be improved, and the threshold voltage Vth can be stabilized.

The method of manufacturing the liquid crystal device 100 according to the present embodiment includes a first step of implanting impurities corresponding to the type and conductivity of the thin film transistor 30 into only a part of the semiconductor layer 31A forming the channel region of the liquid crystal device 100 described above, and a second step of performing, after the first step, the heat treatment on the semiconductor layer 31A a plurality of times at 800° C or higher.

Note that it is preferable that the heat treatment is performed on the semiconductor layer 31A a plurality of times at 800° C or higher, and finally the heat treatment is performed at 1000° C or higher, preferably 1100° C or higher.

In the liquid crystal device 100 described above according to the present embodiment, along the Y axis, the semiconductor layers 31B, 31C of the source region 31s include the semiconductor layer 31B which is a low concentration region lower in concentration of the impurity having conductivity different from that of the impurity as the channel dope than the opposite side to the semiconductor layer 31A side as the channel region, that is, the +Y side. The semiconductor layers 31B, 31C of the drain region 31d include the semiconductor layer 31B that is the LDD (low concentration region) lower in concentration of the impurity having conductivity different from that of impurity as the channel dope than the opposite side to the semiconductor layer 31A side as the channel region, that is, the -Y side.

According to the liquid crystal device 100 described above of the present embodiment, since the semiconductor layer 31 includes the semiconductor layers 31B, 31B, the thin film transistor 30 has the LDD structure, and it is possible to achieve an increase in the breakdown voltage and the improvement of the reliability of the thin film transistor 30.

The projector (electronic apparatus) 1000 of the present embodiment includes the liquid crystal devices 100B, 100G, and 100R configured similarly to the liquid crystal device 100 of the present embodiment described above.

According to the projector 1000 of the present embodiment, it is possible to improve the display performance including the switching speed of the image light emitted from the liquid crystal devices 100B, 100G, and 100R.

Some preferable embodiments of the present disclosure have been described hereinabove in detail. However, the present disclosure is not limited to such specific embodiments, and various modifications and changes can be made thereto within the scope of the key points of the present disclosure set forth in the appended claims.

For example, in the embodiment described above, the transmissive liquid crystal device is exemplified as the liquid crystal device as the electro-optic device, but the electro-optic device may be a reflective liquid crystal device or a liquid crystal device of a liquid crystal on silicon (LCOS) type. In addition, the electro-optic device may be an organic EL device having a layer formed of an organic compound as an electro-optic layer, or may be a device having an electro-optic layer other than the liquid crystal device or the organic EL device.

For example, in the embodiment described above, the projector is exemplified as the electronic apparatus, but the electronic apparatus is not limited to the projector. The electronic apparatus including the electro-optic device described above may be, for example, a stereolithography device, or may be an apparatus that utilizes image light converted by an electro-optic device other than a projector or a stereolithography device.

### Summary of Present Disclosure

The present disclosure will be summarized below as appendices.

(Appendix 1) An electro-optic device including a transistor disposed at a substrate, wherein the transistor includes a semiconductor layer including a channel region, a source region, and a drain region and extending along a first direction, and a gate electrode facing the channel region via an insulating film, an impurity is added to a part of the semiconductor layer in the channel region, and an impurity concentration in a central region of the semiconductor layer in the channel region and an impurity concentration in side regions at both sides of the central region are different from each other in the first direction.

According to the configuration of Appendix 1, it is possible to control the switching characteristics of the thin film transistor in accordance with the type and conductivity of the transistor, stabilize the threshold voltage, increase the drain current in the ON state or decrease the drain current in the OFF state, and improve the switching characteristics of the transistor.

(Appendix 2) The electro-optic device according to Appendix 1, wherein the impurity concentration in the side regions of the semiconductor layer in the channel region is higher than the impurity concentration in the central region.

According to the configuration of Appendix 2, it is possible to appropriately shift the threshold voltage of the transistor to "Enhance" or "Depression", suppress the hump, and improve the switching characteristics of the transistor.

(Appendix 3) The electro-optic device according to Appendix 2, wherein the impurity concentration in the central region of the semiconductor layer is zero.

In the configuration of Appendix 3, when the impurity is not implanted into the central region of the semiconductor layer in the channel region and the central region is an intrinsic semiconductor, the controllability of the switching characteristics of the transistor is enhanced, and the switching characteristics of the transistor can be further improved.

(Appendix 4) The electro-optic device according to one of Appendices 2 and 3, wherein the transistor has a p-type MOS structure, the gate electrode extends along a second direction orthogonal to the first direction and a thickness direction of the substrate, and a dimension in the first direction of the semiconductor layer in the channel region is equal to or larger than a dimension in the first direction of the gate electrode.

In the configuration of Appendix 4, the transistor may have the p-type MOS structure, the side regions of the semiconductor layer in the channel region may overlap at least the gate electrode in the first direction, and the side regions may extend toward both sides in the first direction beyond the gate electrode. According to the configuration of Appendix 4, it is possible to appropriately shift the threshold voltage of the transistor having the p-type MOS structure to "Enhance" or "Depression", suppress the hump, and improve the switching characteristics of the transistor having the p-type MOS structure.

(Appendix 5) The electro-optic device according to Appendix 1, wherein in a second direction orthogonal to the first direction and a thickness direction of the substrate, the semiconductor layer in the channel region includes a central portion including the central region and the side regions, and edge regions at both sides of the central portion, and the impurity concentration in the edge regions of the semiconductor layer is higher than an impurity concentration in the central portion.

According to the configuration of Appendix 5, since the impurity concentration in the edge regions of the semiconductor layer is higher than the effective impurity concentration in the central portion, the threshold voltage represented by the hump characteristics of the transistor can be shifted to "Enhance". Meanwhile, since the impurity concentration in the central portion of the semiconductor layer is lower than the impurity concentration in the edge regions, the threshold voltage of the transistor can be shifted to "Depression". According to the configuration of Appendix 5, it is possible to adjust the impurity concentration in the side regions and the impurity concentration in the edge regions in the central portion of the semiconductor layer, appropriately shift the threshold voltage of the transistor to "Enhance" or "Depression", suppress the hump, and improve the switching characteristics of the transistor compared to the prior-art electro-optic device.

(Appendix 6) The electro-optic device according to Appendix 5, wherein a dimension in the first direction of the edge regions is larger than a dimension of the central portion.

According to the configuration of Appendix 6, it is possible to diffuse the impurity implanted into the edge regions at least within the range in the first direction of the central portion, reliably shift the threshold voltage of the transistor to "Enhance", and enhance the hump characteristics.

(Appendix 7) The electro-optic device according to one of Appendices 5 and 6, wherein the transistor has a p-type MOS structure, the gate electrode extends along the second direction orthogonal to the first direction and the thickness direction of the substrate, the impurity concentration in the side regions of the semiconductor layer in the channel region is higher than the impurity concentration in the central region, and a dimension in the first direction of the semiconductor layer in the channel region is equivalent to a dimension in the first direction of the gate electrode.

In the configuration of Appendix 7, the transistor has the p-type MOS structure, and the central portion of the semiconductor layer in the channel region overlaps the gate electrode in the first direction. In the semiconductor layer, a region to which the impurity as the channel dope is added is formed in the O-shape or the rectangular shape in the plan view. According to the configuration of Appendix 7, it is possible to appropriately shift the threshold voltage of the transistor having the p-type MOS structure to "Enhance" or "Depression", suppress the hump, and enhance the controllability of the switching characteristics of the transistor having the p-type MOS structure.

(Appendix 8) The electro-optic device according to Appendix 7, wherein the impurity concentration in the central region of the semiconductor layer is zero.

In the configuration of Appendix 8, when the impurity is not implanted into the central region of the semiconductor layer in the channel region and the central region is an intrinsic semiconductor, the controllability of the switching characteristics of the transistor having the p-type MOS structure is enhanced, and the switching characteristics of the transistor having the p-type MOS structure can be further improved.

(Appendix 9) The electro-optic device according to one of Appendices 5 and 6, wherein the transistor has an n-type MOS structure, the gate electrode extends along the second direction orthogonal to the first direction and the thickness direction of the substrate, the impurity concentration in the central region of the semiconductor layer in the channel region is higher than the impurity concentration in the side regions, and a dimension in the first direction of the semiconductor layer in the channel region is equivalent to a dimension in the first direction of the gate electrode.

In the configuration of Appendix 9, the transistor has the n-type MOS structure, and the central portion of the semiconductor layer in the channel region overlaps the gate electrode in the first direction. In the semiconductor layer, a region to which the impurity as the channel dope is added is formed in the I-shape in the plan view. According to the configuration of Appendix 9, it is possible to appropriately shift the threshold voltage of the transistor having the n-type MOS structure to "Enhance" or "Depression", suppress the hump, and enhance the controllability of the switching characteristics of the transistor having the n-type MOS structure.

(Appendix 10) The electro-optic device according to Appendix 9, wherein the impurity concentration in the side regions of the semiconductor layer is zero.

In the configuration of Appendix 10, when the impurity is not implanted into the side regions of the semiconductor layer in the channel region and the side regions are intrinsic semiconductors, the controllability of the switching characteristics of the transistor having the n-type MOS structure is enhanced, and the switching characteristics of the transistor having the n-type MOS structure can be further improved.

(Appendix 11) The electro-optic device according to Appendix 10, wherein a length of the semiconductor layer in the second direction orthogonal to the first direction and the thickness direction of the substrate is 1 μm or less.

In the configuration of Appendix 11, it is possible to form a depletion layer in the semiconductor layer forming the source region and the drain region, suppress unevenness of a light leakage current in the electro-optic device and projection flicker of the image light emitted from the electro-optic device to improve the display quality.

(Appendix 12) The electro-optic device according to any one of Appendices 1 to 11, wherein a heat treatment at 800° C or higher is performed a plurality of times after the impurity is added to a part of the semiconductor layer in the channel region.

According to the configuration of Appendix 12, the gate insulating film between the semiconductor layer and the gate electrode in the channel region is baked to sufficiently activate the impurity of the semiconductor layer in the channel region, and the impurity can be prevented from diffusing to an unexpected region through the gate insulating film. According to the configuration of Appendix 11, the switching characteristics of the transistor can be improved, and the threshold voltage can be stabilized.

(Appendix 13) The electro-optic device according to any one of Appendices 1 to 12, wherein in the first direction, the semiconductor layer in the source region has, at the channel region side, a low concentration region lower in concentration of the impurity than an opposite side to the channel region side, and the semiconductor layer in the drain region has, at the channel region side, a low concentration region lower in concentration of the impurity than the opposite side to the channel region side.

According to the configuration of Appendix 13, it is possible to achieve an increase in breakdown voltage and an improvement of the reliability of the transistor.

(Appendix 14) A method of manufacturing the electro-optic device according to Appendix 12, the method including performing a heat treatment at 800° C or higher a plurality of times on the semiconductor layer into which the impurity is implanted and which forms the channel region.

According to the configuration of Appendix 14, the gate insulating film between the semiconductor layer and the gate electrode in the channel region is baked to sufficiently activate the impurity of the semiconductor layer in the channel region, and the impurity can be prevented from diffusing to an unexpected region through the gate insulating film. According to the configuration of Appendix 14, the switching characteristics of the transistor of the electro-optic device can be improved, and the threshold voltage can be stabilized.

(Appendix 15) An electronic apparatus including the electro-optic device according to any one of Appendices 1 to 13.

According to the configuration of Appendix 15, since the electro-optic device described above is provided, it is possible to suppress a deterioration of display quality in the electronic apparatus based on the image light emitted from the liquid crystal device.

What is claimed is:

1. An electro-optic device comprising
a transistor disposed at a substrate, wherein
the transistor includes
a semiconductor layer including a channel region, a source region, and a drain region and extending along a first direction, and
a gate electrode facing the channel region via an insulating film,
an impurity is added to a part of the semiconductor layer in the channel region, and
an impurity concentration in a central region of the semiconductor layer in the channel region and an impurity concentration in side regions at both sides of the central region are different from each other in the first direction.

2. The electro-optic device according to claim 1, wherein
the impurity concentration in the side regions of the semiconductor layer in the channel region is higher than the impurity concentration in the central region.

3. The electro-optic device according to claim 2, wherein
the impurity concentration in the central region of the semiconductor layer is zero.

4. The electro-optic device according to claim 2, wherein
the transistor has a p-type MOS structure,
the gate electrode extends along a second direction orthogonal to the first direction and a thickness direction of the substrate, and
a width in the first direction of the semiconductor layer in the channel region is equal to or larger than a width in the first direction of the gate electrode.

5. The electro-optic device according to claim 1, wherein
in a second direction orthogonal to the first direction and a thickness direction of the substrate,
the semiconductor layer in the channel region includes a central portion including the central region and the side regions, and edge regions at both sides of the central portion, and
the impurity concentration in the edge regions is higher than an impurity concentration in the central portion.

6. The electro-optic device according to claim 5, wherein
a width in the first direction of the edge regions is larger than a width in the first direction of the central portion.

7. The electro-optic device according to claim 5, wherein
the transistor has a p-type MOS structure,
the gate electrode extends along the second direction orthogonal to the first direction and the thickness direction of the substrate,
the impurity concentration in the side regions of the semiconductor layer in the channel region is higher than the impurity concentration in the central region, and
a width along the first direction of the semiconductor layer in the channel region is equivalent to a width along the first direction of the gate electrode.

8. The electro-optic device according to claim 7, wherein
the impurity concentration in the central region of the semiconductor layer is zero.

9. The electro-optic device according to claim 5, wherein
the transistor has an n-type MOS structure,
the gate electrode extends along the second direction orthogonal to the first direction and the thickness direction of the substrate,
the impurity concentration in the central region of the semiconductor layer in the channel region is higher than the impurity concentration in the side regions, and
a width in the first direction of the semiconductor layer in the channel region is equivalent to a width in the first direction of the gate electrode.

10. The electro-optic device according to claim 9, wherein
the impurity concentration in the side regions of the semiconductor layer is zero.

11. The electro-optic device according to claim 10, wherein
a length of the semiconductor layer in the second direction orthogonal to the first direction and the thickness direction of the substrate is 1 μm or less.

12. The electro-optic device according to claim 1, wherein
a heat treatment is performed a plurality of times after the impurity is added to the part of the semiconductor layer in the channel region.

13. The electro-optic device according to claim 1, wherein
in the first direction, the semiconductor layer in the source region has, at the channel region side, a low concentration region lower in concentration of the impurity than an opposite side to the channel region side, and
in the first direction, the semiconductor layer in the drain region has, at the channel region side, a low concentration region lower in concentration of the impurity than the opposite side to the channel region side.

14. A method of manufacturing the electro-optic device according to claim 12, the method comprising
performing a heat treatment at 800°C or higher a plurality of times on the semiconductor layer into which the impurity is implanted and which forms the channel region.

15. An electronic apparatus comprising
the electro-optic device according to claim 1.
